(19) United States
(12) Patent Application Publication
(10) Pub. No.: US 2007/0268034 A1
(43) Pub. Date: Nov. 22, 2007

(54) METHOD AND APPARATUS FOR SETTING OF APPLIANCE-SPECIFIC EVALUATION PARAMETERS

(75) Inventors: Uwe Kramer, Dresden (DE); Frank Voss, Langebrueck (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Qimonda AG, Muenchen (DE)

(21) Appl. No.: 11/750,079

(22) Filed: May 17, 2007

(30) Foreign Application Priority Data
May 17, 2006 (DE) 10 2006 023 196.1

(51) Int. Cl. G01R 31/02

(52) U.S. Cl. 324/754

(57) ABSTRACT

A method and apparatus for setting appliance-specific evaluation parameters in an instrument is disclosed. In one embodiment, a structure is measured using a reference measurement apparatus or a measurement apparatus, and the recorded measurement data is transmitted to the respective other of the two appliances. The measurement data is contained in the data memory of both the instrument and of the reference instrument. The measurement data items are then evaluated by the evaluation device and the reference evaluation device by determining a determined structure size and a reference structure size. The determined structure size is compared with the reference structure size, and the evaluation parameters of the evaluation device are varied until the difference between the determined structure size and the reference structure size is less than a predetermined value.

### CROSS-REFERENCE TO RELATED APPLICATIONS

This Utility Patent Application claims priority to German Patent Application No. DE 10 2006 023 196.1 filed on May 17, 2006, which is incorporated herein by reference.

### BACKGROUND

The present description relates to a method and an apparatus for setting of appliance-specific evaluation parameters in an instrument. In one embodiment, an instrument in each case has a measurement apparatus and an appliance-specific evaluation device. The appliance-specific evaluation parameters can be determined and set as a function of a reference instrument, which once again has a reference measurement apparatus and a reference evaluation device.

During the production of semiconductor components such as DRAM memory modules (dynamic random access memory), non-volatile memory modules, logic circuits, optoelectronic components or MEMS (micro-electro-mechanical systems), the associated integrated circuits are first of all processed at wafer level. After completion of the manufacturing processes, the wafer is split into chips which each contain the corresponding circuits, and are packed in suitable packages in order to produce the semiconductor components.

In order to produce any given semiconductor component, the wafer passes through a multiplicity of structuring processes during which, inter alia, layers are deposited and structured, for example. During the production of memory modules, in particular, arrangements of lines are produced, in particular word lines and bit lines, which are each arranged in the form of a regular grid.

After completion of the corresponding circuits at wafer level, a check is carried out to determine whether the structured elements are within the specifications intended for the respective elements. A measurement is thus carried out, for example, using a scanning electron microscope (SEM) to determine whether the individual word lines and bit lines have the intended interconnect width and the intended distance between the respective interconnects.

The definition of specifications to be complied with is worthwhile when the measurement of a predetermined line width produces identical results in all of the instruments. For this reason, it is desirable for the evaluation parameters to be matched to one another in all the appliance-specific evaluation devices such that identical measurement results are obtained.

In order to match the appliance-specific evaluation device, a structured width is, for example, sent to the various instruments, where it is measured. In particular, wafers from a plurality of critical processes are sent from the development factory to the next factory for worldwide matching of CD-SEM instruments (“tools”). These wafers are then measured using high statistics in both factories. The measurement results are compared for matching, and the evaluation parameters are matched to one another.

For these and other reasons, there is a need for the present invention.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a schematic view of a scanning electron microscope.

FIG. 2A illustrates an example of a structure to be measured.

FIG. 2B illustrates an example of a waveform which is obtained after measurement of the structure illustrated in FIG. 2A.

FIG. 3 illustrates a block diagram of the method according to one embodiment.

FIG. 4 illustrates a block diagram of a further process in the method according to one embodiment.

FIG. 5 illustrates an example of a brightness distribution, which can be evaluated using the method according to one embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

An instrument has a measurement apparatus and an appliance-specific evaluation device. The evaluation parameters are determined in the instrument as a function of a reference instrument. The reference instrument once again has a reference measurement apparatus and a reference evaluation device.

According to one embodiment, in a first process a structure is measured using the reference measurement apparatus and the measurement apparatus, and the recorded measurement data is transmitted to the respective other of the two appliances. In consequence, the measurement data is contained in the data memories of both the instrument and of the reference instrument. The respectively identical measurement data items are then evaluated by the evaluation device and the reference evaluation device, by determining a determined structure size and a reference structure size. The determined structure size is compared with the reference structure size, and the evaluation parameters of the evaluation device are varied until the determined structure size approximately matches the reference structure size, or the difference between the determined structure size and the reference structure size is less than a predetermined value. The predetermined value is any desired minimum difference value, and may also be zero.

Since the characteristic structure size is determined from the raw data in each case using different evaluation devices, specifically on the one hand the evaluation device of the master appliance and on the other hand the receiving instrument, it is possible by a simple comparison of the determined characteristic structure sizes to determine whether the appliance-specific evaluation parameters of the receiving instrument match those of the master instrument. This means, for example, that there is no need to send wafers in order to set and monitor the matching of the evaluation parameters. In consequence, it is possible to determine the matching exactly without any influence of transport-dependent size changes. Furthermore, the method according to the invention saves time and reduces the measurement complexity.

One or more embodiments provide the raw data of the measurement signals of the connected reference instruments are input upstream of the appliance-specific image processing path on the respective instruments. For example, the raw signals are recorded during the determination of the enlargement by the master instrument, while the raw signal for determination of contrast and brightness are recorded by the receiving instrument. However, the raw signals may also each be recorded by the other instrument and, of course, the raw signal for determination of the enlargement and for determination of the contrast and brightness may each be recorded by a single instrument.

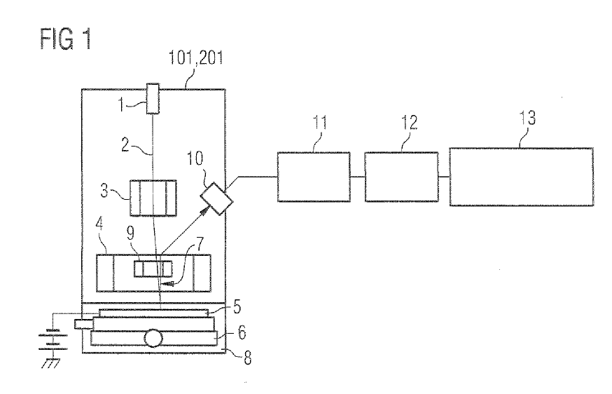

FIG. 1 illustrates the major components of an example of a scanning electron microscope which, for example, may be the measurement apparatus.

The scanning electron microscope 101 has an electron beam source 1 for production of an electron beam 2 which is deflected in the XY direction by a deflection device 3. Reference symbol 4 denotes an objective lens apparatus for focusing of the electron beam 2 onto the substrate to be examined. A wafer 5 to be examined is held in a sample chamber 8 on a sample holder or object mount 6 which can be moved in the XY direction. An electron beam or secondary electron beam 7 reflected from the wafer 5 is deflected by an ExB deflection device 9, and is passed to a detector 10 in which it is verified and if necessary amplified. The signal that is produced is converted in an A/D converter 11 to a digital signal which, for example, corresponds to one of the 256 gray-scale levels, and is stored together with the corresponding position coordinates in a memory device 12. The image data that is produced is processed in the image processing device or evaluation device 13, so that the characteristic structure sizes of the measured structure are obtained as the result.

In general, it can be assumed that the measurement results of the scanning electron microscope 1 are not appliance-specific provided that identical scanning electron microscopes from the same manufacturer are used. In contrast, the results which are obtained by the evaluation of the image data in the evaluation device 13 are subject to appliance-specific fluctuations. For example, one and the same wafer which is measured using two different appliances will have different characteristic structure sizes, in particular because the appliance-specific evaluation parameters differ in different instruments even from the same manufacturer. These appliance-specific evaluation parameters will be illustrated somewhat more clearly in the following text.

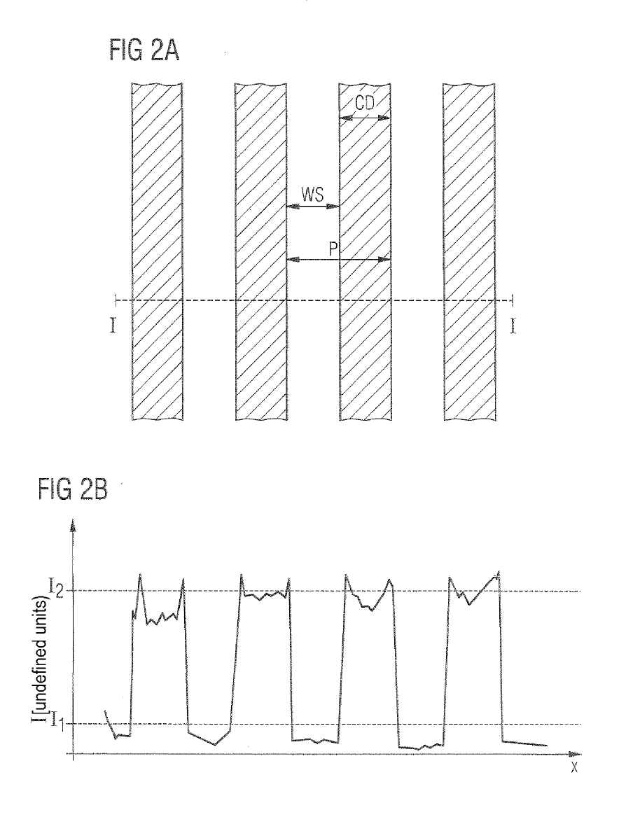

FIG. 2A illustrates a plan view of a pattern 16—by way of example transferred using a photolithographic process—which is intended to be examined using a scanning electron microscope. FIG. 2A illustrates in particular the characteristic sizes of the line width (CD “critical dimension”), column width WS and repetition size or period (P “pitch”). FIG. 2B illustrates an associated waveform which can be obtained, for example, during an electron-microscope examination of this structure. FIG. 2B illustrates the intensity, I(x) as a function of x. When assessing the characteristic variables from this waveform, x areas could be identified with an I(x) value less than a first predetermined threshold I₁ as white areas (column areas=spaces), while x areas which are in this case between two maxima of I(x) will be identified with an I(x) value between the first predetermined threshold value I₁ and a second predetermined threshold value I₂ as dark areas (lines). X areas with an I(x) value which is greater than I₂ will be identified as edge areas. During the evaluation of waveforms such as this, which is normally done in the evaluation device 13, the waveform can be compressed or expanded in the x direction by, for example, variation of the “magnification” evaluation parameter. The associated waveform would be extended or compressed in a direction at right angles to the x direction by variation of the contrast. The waveform would essentially be shifted at right angles to the x direction, upwards or downwards, by variation of the “brightness” parameter.

The magnification defines the repetition size (pitch) of the structure, while the contrast and brightness essentially govern the line width and the column width. A further parameter is the depth of focus. In particular, the width of the edge of the structure is reproduced accurately by correct adjustment of the depth of focus.

The parameters magnification, contrast and brightness are calibrated differently in the evaluation devices in different appliances.

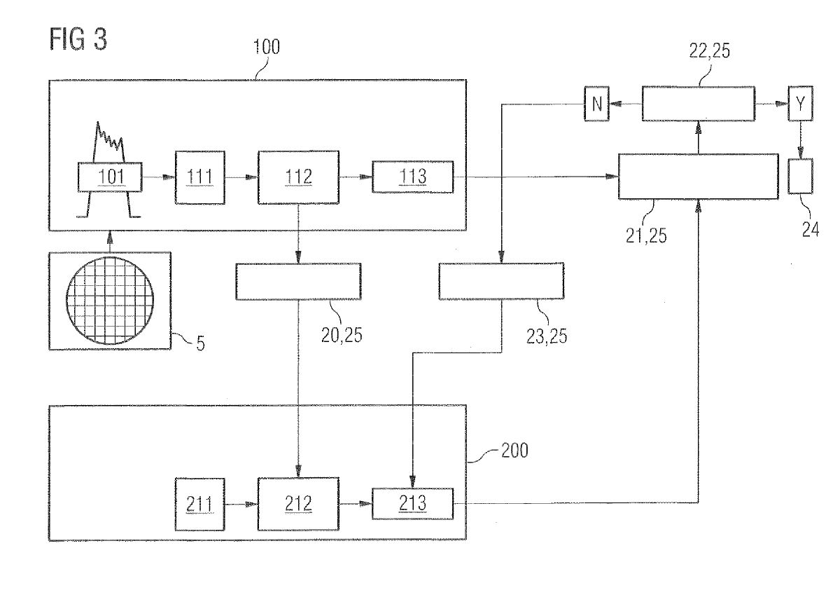

FIG. 3 illustrates a master instrument 100 which has a scanning electron microscope 101, an analog/digital converter 111, a memory device 112 and an image processing device 113. The scanning electron microscope may, for example, be designed as illustrated in FIG. 1. A device 20 is provided, which is suitable for transferring measurement data from the master instrument 100 to the receiving instrument 200. By way of example, the transfer takes place from the memory device 112 of the master instrument to the memory device 212 of the receiving instrument 200. By way of example, the digitized data is transmitted during this process. The device 20 is, for example, in the form of transfer software.

The apparatus 25 according to the invention for setting of appliance-specific evaluation parameters furthermore has a comparison device 21 which is suitable for comparison of determined measurement variables with one another. For example, the determined structure sizes are transferred from the image processing device 213 of the receiving instrument 200 to the comparison device. Furthermore, the reference structure sizes are transferred from the image processing device 113 of the master instrument 100 to the comparison device 21. The comparison device 21 is connected to an assessment device 22 which assesses whether the difference that has been formed is or is not below a predetermined threshold value. The assessment device 22 is also connected to a control device 23 which—depending on the result achieved in the assessment device 22—varies the evaluation parameters in the evaluation device of the receiving instrument 200.

The method procedure according to one embodiment is as follows. Any given wafer 5 is measured using the master instrument 100. The wafer 5 is normally structured, for example having one or more patterns, which have a structure as is illustrated in FIG. 2A. By way of example, the raw data is recorded in the scanning electron microscope 101 of the master instrument 100, and is digitized in the A/D converter 111. The recorded raw data, that is to say by way of example the gray-scale level, is stored as a function of the position coordinates in the memory device 112, and is transferred without any further processing via the transfer software 20 to the memory device 212 for the receiving instrument 200.

The raw data is then evaluated in the master instrument 100 using the master-appliance-specific evaluation parameters, with a characteristic structure variable of the examined structure being determined, in the present case the horizontal or the vertical pitch. The structure size determined by the evaluation device 113 of the master instrument 100 corresponds to the reference structure size SM. Furthermore, the image data transmitted to the receiving instrument 200 is evaluated using the appliance-specific evaluation parameters of the receiving instrument 200, and the same characteristic structure size is determined. The structure size determined by the evaluation device 213 of the receiving instrument 200 corresponds to the determined structure size SR. The reference structure size SM, which has been determined by the master instrument 100, is now compared with the determined structure size SR, which has been determined by the receiving instrument 200, in the comparison device 21. By way of example the horizontal or vertical pitch values are each compared with one another in this case as characteristic structure variables SM, SR. The assessment device 22 is then used to assess whether the discrepancy between the determined structure size SR and the reference structure size SM is or is not greater than a specific threshold value. If the threshold value has been exceeded, then the evaluation parameter to be set is varied in the receiving instrument 200. A new value of the structure size is then determined with the changed evaluation parameters in the evaluation device of the receiving instrument 200, and is compared with the reference structure size SM. This process is repeated until the assessment device 22 finds that the discrepancy is less than a predetermined threshold value.

The evaluation parameter magnification/field of view is thus in each case defined in the x direction and in the y direction by determination and comparison of the horizontal and vertical pitch.

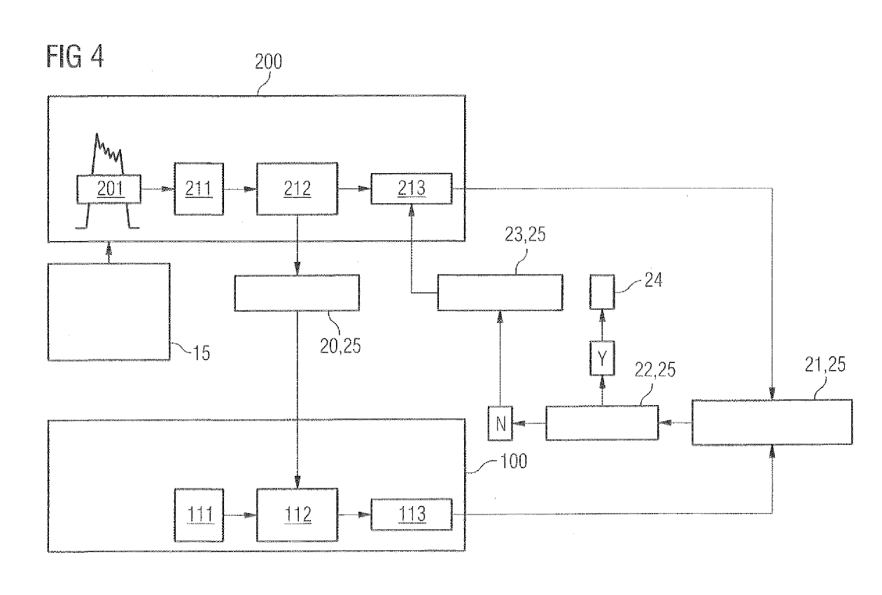

The method illustrated in FIG. 4 can then be used to set the brightness/contrast evaluation parameter. In this case, it is necessary to ensure that, for example before the processes which now follow are carried out, the evaluation parameter “magnification” has already been defined as described with reference to FIG. 3.

As illustrated in FIG. 4, any given sample 15 is now measured by the receiving instrument 200 in order to set the evaluation parameter of brightness/contrast. The undefined sample 15 is, in particular, an obstructed structure, for example a metal surface, which is normally used for reference measurements in scanning electron microscopes, or an unstructured semiconductor wafer.

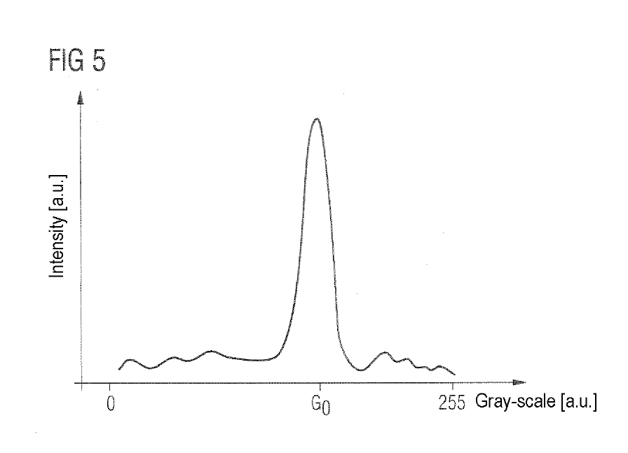

This results, for example, in an SEM image on the receiving instrument 200. The SEM image can be digitized in the A/D converter 211, and the corresponding image data is stored, for example, in the memory device 212. The image data obtained is then analyzed using the evaluation device 213 and predetermined, instrument-specific evaluation parameters, with a histogram being determined, as is illustrated by way of example in FIG. 5. A histogram such as this indicates the distribution of the intensity as a function of the gray-scale level. An unstructured surface in this case normally has a single gray-scale value, and thus a single maximum. The evaluation parameters could also be determined by examining a sample surface which has a plurality of maxima, although the histogram should have identifiable maxima. The evaluation parameters of the evaluation device 213 determine the position Go of the maximum with respect to the gray-scale axis.

Furthermore, the image data recorded by the receiving instrument is sent without any manipulation whatsoever by the settings of the receiving instrument 200 to the master instrument by using the data transfer device 20, and is stored in the memory device 112. The image data is evaluated in the evaluation device 113 using the master instrument 100 settings, once again with a histogram being determined in the present example.

By way of example, the position of the maximum Go as determined by the evaluation device 213 is then compared in the comparison device 21 with the reference position of the maximum determined by the master instrument 100. The assessment device 22 determines whether the difference is below or above a predetermined threshold value. If the predetermined threshold value is exceeded, then the control device 23 adjusts the evaluation parameters in the evaluation device 213 of the receiving tool 200, and the raw data is evaluated once again by the evaluation device 213 of the receiving instrument 200, resulting in a histogram which has been shifted along the gray-scale axis.

The newly determined position of the maximum Go is, for example, once again compared in the comparison device 21 with the reference position, and the assessment device 22 is once again used to determine whether the difference is below or above a predetermined threshold value. This process can be carried out until the discrepancy is within a predetermined tolerance band, and, in consequence, the evaluation parameters of contrast and brightness are matched to the evaluation parameters of the master instrument 100.

In order to improve the matching between the master instrument 100 and the receiving instrument by evaluation of the measurement data that has already been recorded by the master instrument 100, the line width and/or column width of the measured pattern can optionally be determined, with these being compared with one another. The evaluation parameters of the receiving instrument are varied until an optimum match is obtained between the determined measurement values.

In the embodiments illustrated in FIGS. 3 and 4, the apparatus for setting of appliance-specific evaluation parameters in each case has on the one hand the data transfer device 20, the comparison device 21 for comparison of the measured value which have in each case been determined by the evaluation device 113 of the master instrument 100 and the evaluation device 213 of the receiving instrument 200. The apparatus furthermore has the assessment device 22, which determines whether the comparison result is below or above a predetermined threshold value, as well as a control device 23, which calculates the parameters to be set once again, and sets them on the evaluation device. The apparatus for setting of appliance-specific evaluation parameters is in the form of specific software, whose function includes data transfer, comparison of the measured values, assessment of the comparison result and readjustment of the parameters in the evaluation device.

For the purposes of the method, the appliance which is in each case used to record the measurement data is irrelevant. This means that the master instrument or the receiving instrument can in each case be used for data recording. The evaluation parameters in the evaluation device of the receiving instrument may, for example, be set using the method.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for operating an instrument comprising:
measuring a structure using a reference measurement apparatus, including obtaining a first set of measurement data;
determining a first reference structure size, with the first set of measurement data being evaluated by a reference evaluation device;
transmitting the first set of measurement data to the instrument, determining a first determined structure size with the first set of measurement data being evaluated by the evaluation device using an appliance-specific evaluation parameter set;
comparing the first determined structure size with the first reference structure size; and
varying the appliance-specific evaluation parameter set in the evaluation device until the difference between the first determined structure size and the first reference structure size is less than a predetermined value.

2. The method of claim 1, comprising:
measuring a sample surface using the measurement apparatus, with a second set of measurement data being obtained;
determining a determined gray-scale distribution with the second set of measurement data being evaluated by the evaluation device using an appliance-specific evaluation parameter set;
transmitting the second set of measurement data to the reference instrument;
determining a reference gray-scale distribution with the second set of measurement data being evaluated by the reference evaluation device;
comparing the determined gray-scale distribution with the reference gray-scale distribution; and
varying the appliance-specific evaluation parameter set in the evaluation device until the difference between the determined gray-scale distribution of the reference gray-scale distribution is less than a predetermined value.

3. The method of claim 1, comprising:
measuring a sample surface using the reference measurement apparatus, with a second set of measurement data being obtained;
determining a reference gray-scale distribution with the second set of measurement data being evaluated by the reference evaluation device;
transmitting the second set of measurement data to the reference instrument;
determining the determined gray-scale distribution with the second set of measurement data being evaluated by the evaluation device using an appliance-specific evaluation parameter set;
comparing the determined gray-scale distribution with the reference gray-scale distribution; and
varying the appliance-specific evaluation parameter set in the evaluation device until the difference between the determined gray-scale distribution and the reference gray-scale distribution is less than a predetermined value.

4. A method for setting of appliance-specific evaluation parameters in an instrument, which in each case has a measurement apparatus and an appliance-specific evaluation device, as a function of a reference instrument which has a reference measurement apparatus and a reference evaluation device, comprising:
measuring a structure using the reference measurement apparatus, with a first set of measurement data being obtained;
determining a first reference structure size, with the first set of measurement data being evaluated by the reference evaluation device;
transmitting the first set of measurement data to the instrument, determining a first determined structure size with the first set of measurement data being evaluated by the evaluation device using an appliance-specific evaluation parameter set;
comparing the first determined structure size with the first reference structure size; and
varying the appliance-specific evaluation parameter set in the evaluation device until the difference between the first determined structure size and the first reference structure size is less than a predetermined value.

5. The method of claim 4, comprising:
measuring a sample surface using the measurement apparatus, with a second set of measurement data being obtained;
determining a determined gray-scale distribution with the second set of measurement data being evaluated by the evaluation device using an appliance-specific evaluation parameter set;
transmitting the second set of measurement data to the reference instrument;
determining a reference gray-scale distribution with the second set of measurement data being evaluated by the reference evaluation device;
comparing the determined gray-scale distribution with the reference gray-scale distribution; and
varying the appliance-specific evaluation parameter set in the evaluation device until the difference between the determined gray-scale distribution of the reference gray-scale distribution is less than a predetermined value.

6. The method of claim 4, comprising:
measuring a sample surface using the reference measurement apparatus, with a second set of measurement data being obtained;
determining a reference gray-scale distribution with the second set of measurement data being evaluated by the reference evaluation device;
transmitting the second set of measurement data to the reference instrument;
determining the determined gray-scale distribution with the second set of measurement data being evaluated by the evaluation device using an appliance-specific evaluation parameter set;
comparing the determined gray-scale distribution with the reference gray-scale distribution; and
varying the appliance-specific evaluation parameter set in the evaluation device until the difference between the determined gray-scale distribution and the reference gray-scale distribution is less than a predetermined value.

7. The method of claim 4, comprising determining a further reference structure size with the first set of measurement data being evaluated by the reference evaluation device;
determining a further determined structure size with the first set of measurement data being evaluated by the evaluation device using a further appliance-specific evaluation parameter set;
comparing the further determined structure size with the further reference structure size; and
varying the further appliance-specific evaluation parameter set in the evaluation device until the difference between the further determined structure size and the further reference structure size is less than a predetermined value.

8. The method of claim 4, comprising wherein the structure to be measured has a regular line and column grid with a constant period, and the first characteristic structure size is the horizontal period or the vertical period.

9. The method of claim 7, wherein the structure to be measured comprises a line column grid, and the further characteristic structure variable is the line width or the column width.

10. The method of claim 5, comprising wherein the sample surface is unstructured.

10. A method for setting of appliance-specific evaluation parameters in an instrument, which in each case has a measurement apparatus and an appliance-specific evaluation device, as a function of a reference instrument which has a reference measurement apparatus and a reference evaluation device, comprising:
measuring a structure using the measurement apparatus, with a first set of measurement data being obtained;
determining a first determined structure size with the first set of measurement data being evaluated by the evaluation device using an appliance-specific evaluation parameter set;
transmitting the first set of measurement data to the reference instrument;
determining a first reference structure size with the first set of measurement data being evaluated by the reference evaluation device; and
varying the appliance-specific evaluation parameter set in the evaluation device until the difference between the first determined structure size and the first reference structure size is less than a predetermined value.

11. The method of claim 10, comprising:
measuring a sample surface using the measurement apparatus, with a second set of measurement data being obtained;
determining a determined gray-scale distribution with the second set of measurement data being evaluated by the evaluation device using an appliance-specific evaluation parameter set;
transmitting the second set of measurement data to the reference instrument;
determining a reference gray-scale distribution with the second set of measurement data being evaluated by the reference evaluation device;
comparing the determined gray-scale distribution with the reference gray-scale distribution; and
varying the appliance-specific evaluation parameter set in the evaluation device until the difference between the determined gray-scale distribution of the reference gray-scale distribution is less than a predetermined value.

12. The method of claim 10, comprising:
measuring a sample surface using the reference measurement apparatus, with a second set of measurement data being obtained;
determining a reference gray-scale distribution with the second set of measurement data being evaluated by the reference evaluation device;
transmitting the second set of measurement data to the reference instrument;
determining the determined gray-scale distribution with the second set of measurement data being evaluated by the evaluation device using an appliance-specific evaluation parameter set;
comparing the determined gray-scale distribution with the reference gray-scale distribution; and
varying the appliance-specific evaluation parameter set in the evaluation device until the difference between the determined gray-scale distribution and the reference gray-scale distribution is less than a predetermined value.

13. The method of claim 10, comprising
determining a further reference structure size with the first set of measurement data being evaluated by the reference evaluation device;
determining a further determined structure size with the first set of measurement data being evaluated by the evaluation device using a further appliance-specific evaluation parameter set;
comparing the further determined structure size with the further reference structure size; and
varying the further appliance-specific evaluation parameter set in the evaluation device until the difference between the further determined structure size and the further reference structure size is less than a predetermined value.

14. The method of claim 10, wherein the structure to be measured has a regular line and column grid with a constant period, and the first characteristic structure size is the horizontal period or the vertical period.

15. The method of claim 14, wherein the structure to be measured comprises a line column grid, and the further characteristic structure variable is the line width or the column width.

16. The method of claim 11, wherein the sample surface is unstructured.

17. An apparatus for setting of appliance-specific evaluation parameters in an instrument which has a measurement apparatus and an appliance-specific evaluation device, as a function of a reference instrument which has a reference measurement apparatus and a reference evaluation device, comprising:
a data transmission device which is suitable for transmission of measurement data from the instrument to the reference instrument or from the reference instrument to the instrument;
a comparison device, which is suitable for comparison of a measurement variable determined by the evaluation device with a reference measurement variable determined by the reference evaluation device, with the comparison device determining a comparison result;
an assessment device, configured to determine whether the comparison result is below or above a predetermined threshold value; and
a control device, which is configured for recalculation of the evaluation parameters to be set and for setting them on the evaluation device.

18. The apparatus of claim 17, comprising wherein the control device is suitable for setting the newly calculated evaluation parameter on the appliance-specific evaluation device.

19. An arrangement of instruments comprising:
an instrument which has a measurement apparatus and an appliance-specific evaluation device;
a reference instrument which has a reference measurement apparatus and a reference evaluation device, as well as an apparatus for setting appliance-specific evaluation parameters in the instrument as a function of the reference instrument, with the apparatus for setting the appliance-specific evaluation parameters having a data transmission device which is suitable for transmission of measurement data from the instrument to the reference instrument or from the reference instrument to the instrument;
a comparison device which is connected to the reference evaluation device and to the appliance-specific evaluation device and is suitable for comparison of a measurement variable determined by the evaluation device with a reference measurement variable determined by the reference evaluation device, with the comparison device determining a comparison result;
an assessment device, which is suitable for finding out whether the comparison result is below or above a predetermined threshold value, and
a control device, which is suitable for recalculation of the evaluation parameters to be set and for setting them on the evaluation device.

20. The arrangement of claim 19, comprising wherein the control device is suitable for setting the newly calculated evaluation parameter on the appliance-specific evaluation device.
